(19) United States
(12) Patent Application Publication
(10) Pub. No.: US 2016/0143174 A1
(43) Pub. Date: May 19, 2016

(54) ANISOTROPIC CONDUCTIVE FILM AND DISPLAY DEVICE HAVING THE SAME

(71) Applicant: SAMSUNG DISPLAY CO., LTD., Yongin-si (KR)

(72) Inventor: Youngmin CHO, Seongnam-si (KR)

(21) Appl. No.: 14/942,658

(22) Filed: Nov. 16, 2015

(30) Foreign Application Priority Data
Nov. 18, 2014 (KR) 10-2014-0161014

(51) Int. Cl. H05K 7/06; H05K 1/18; H05K 1/14; H05K 1/02; H05K 1/11

(52) U.S. Cl. CPC H05K 7/06; H05K 1/0296; H05K 1/117; H05K 1/147; H05K 1/181; H05K 2201/09945

(57) ABSTRACT

A display device includes: a substrate having a pad area; a conductive pad on the pad area; a circuit member on the conductive pad, the circuit member including a bump overlapping the conductive pad; and an anisotropic conductive film between the conductive pad and the bump, the anisotropic conductive film electrically connecting the conductive pad and the bump. The anisotropic conductive film includes: an adhesive layer; at least one conductive particle positioned within the adhesive layer; and a first guide pattern positioned at a surface of the adhesive layer adjacent to the conductive pad.

### CROSS-REFERENCE TO RELATED APPLICATION

This application claims priority to, and the benefit of, Korean Patent Application No. 10-2014-0161014, filed on Nov. 18, 2014 with the Korean Intellectual Property Office, the disclosure of which is incorporated herein in its entirety by reference.

### BACKGROUND

1. Field

Embodiments of the present invention relate generally to flat panel displays. More specifically, embodiments of the present invention relate to an anisotropic conductive film and to a display device mounted with a driving chip or a flexible printed circuit board using the anisotropic conductive film.

2. Description of the Related Art

Flat panel display devices, such as liquid crystal displays and organic light emitting displays, generally include a plurality of electrode pairs generating an electric field and an electro-optical active layer interposed therebetween. The liquid crystal display (LCD) may include a liquid crystal layer as the electro-optical active layer, and the organic light emitting display may include an organic light emitting layer as the electro-optical active layer.

Display devices may generally include a driving chip or a flexible printed circuit board mounted on an edge portion of their display panel. For example, a driving chip may be directly mounted on the display panel using an anisotropic conductive film (ACF) in a chip on glass (COG) manner, or a tape carrier package (TCP) mounted with an integrated circuit or a chip on film (COF) may be connected to the display panel using an ACF.

However, as display devices have achieved higher definition and minimized their non-display area, their wirings have been reduced in width and become more densely disposed, with smaller gaps therebetween. Accordingly, it has become more difficult to stably arrange and bond a conductive pad and a driving chip or a bump of a flexible printed circuit board through an anisotropic conductive film on a substrate; and it has also become more difficult to place conductive particles dispersed within the anisotropic conductive film between the conductive pad and the bump.

It is to be understood that this background of the technology section is intended to provide useful background for understanding the technology and as such disclosed herein, the technology background section may include ideas, concepts or recognitions that were not part of what was known or appreciated by those skilled in the pertinent art prior to a corresponding effective filing date of subject matter disclosed herein.

### SUMMARY

Embodiments of the present invention are directed to a display device capable of stably connecting a driving chip or a flexible printed circuit board to a conductive pad, using an anisotropic conductive film that includes a first guide pattern.

According to an embodiment of the present invention, a display device includes: a substrate having a pad area; a conductive pad on the pad area; a circuit member on the conductive pad, the circuit member including a bump overlapping the conductive pad; and an anisotropic conductive film between the conductive pad and the bump, the anisotropic conductive film electrically connecting the conductive pad and the bump. The anisotropic conductive film includes: an adhesive layer; at least one conductive particle positioned within the adhesive layer; and a first guide pattern positioned at a surface of the adhesive layer adjacent to the conductive pad.

The display device may further include a second guide pattern positioned at another surface of the adhesive layer.

At least part of the first guide pattern may overlap the second guide pattern.

The first guide pattern and the second guide pattern may be disposed within the adhesive layer.

The first guide pattern and the second guide pattern may each have a hardness greater than a hardness of the adhesive layer.

The display device may further include a resin layer on another surface of the adhesive layer, the resin layer having a first surface facing the adhesive layer and a second surface opposite to the first surface; and a second guide pattern positioned at the second surface of the resin layer.

The conductive particles may have a higher density between the first guide patterns than on the first guide pattern.

The display device may further comprise a plurality of the conductive pads and a plurality of the bumps, ones of the conductive pads positioned to correspond to ones of the bumps so as to form pairs of the conductive pads and bumps. The first guide pattern and the second guide pattern may be disposed in alternating manner with the pairs of the conductive pads and bumps.

The display device may further comprise a plurality of the conductive pads and a plurality of the bumps. The first guide pattern and the second guide pattern may be disposed in alternating manner with respect to at least one of the conductive pads and at least one of the bumps.

The first guide pattern and the second guide pattern may each have a height less than a diameter of the conductive particle.

The first guide pattern and the second guide pattern may be provided in one of a linear pattern and a mesh pattern.

The circuit member may be one of a driving chip and a flexible printed circuit board.

According to an embodiment of the present invention, an anisotropic conductive film includes: a base film; an adhesive layer on the base film; at least one conductive particle positioned within the adhesive layer; and a first guide pattern positioned at a surface of the adhesive layer.

The anisotropic conductive film may further include a second guide pattern positioned at another surface of the adhesive layer.

The first guide pattern and the second guide pattern may be disposed within the adhesive layer.

The first guide pattern and the second guide pattern may each have a hardness greater than a hardness of the adhesive layer.

The first guide pattern may be disposed within the adhesive layer, and the second guide pattern may protrude from another surface of the adhesive layer.

The first guide pattern may have a hardness greater than a hardness of the adhesive layer, and the second guide pattern may have a hardness substantially the same as the hardness of the adhesive layer.

The anisotropic conductive film may further include a resin layer on another surface of the adhesive layer, the resin layer having a first surface facing the adhesive layer and a second surface opposite to the first surface; and a second guide pattern positioned at the second the surface of the resin layer.

The first guide pattern and the second guide pattern may each have a height less than a diameter of the conductive particle.

According to an embodiment of the present invention, a display device may efficiently control flow of conductive particles dispersed within an anisotropic conductive film, may prevent short defects between conductive pads, and may electrically connect a bump of a circuit member and a conductive pad even with a relatively small amount of conductive particles.

The foregoing is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

The above and other features and aspects of the present disclosure of invention will be more clearly understood from the following detailed description taken in conjunction with the accompanying drawings, in which:

FIG. 1 is a schematic perspective view illustrating an anisotropic conductive film according to a first exemplary embodiment;

FIG. 2 is a cross-sectional view taken along line I-I;

FIG. 3 is a schematic perspective view illustrating the inside of the anisotropic conductive film of FIG. 1;

FIG. 4 is a schematic perspective view illustrating an anisotropic conductive film according to a second exemplary embodiment;

FIG. 5 is a schematic perspective view illustrating an anisotropic conductive film according to a third exemplary embodiment;

FIG. 6 is a schematic perspective view illustrating an anisotropic conductive film according to a fourth exemplary embodiment;

FIG. 7 is a schematic perspective view illustrating an anisotropic conductive film according to a fifth exemplary embodiment;

FIG. 8 is a schematic cross-sectional view illustrating an anisotropic conductive film according to a sixth exemplary embodiment;

FIG. 9 is a schematic cross-sectional view illustrating an anisotropic conductive film according to a seventh exemplary embodiment;

FIG. 10 is a schematic cross-sectional view illustrating an anisotropic conductive film according to an eighth exemplary embodiment;

FIG. 11 is a schematic cross-sectional view illustrating an anisotropic conductive film according to a ninth exemplary embodiment;

FIG. 12 is a schematic cross-sectional view illustrating an anisotropic conductive film according to a tenth exemplary embodiment;

FIG. 13 is a schematic perspective view illustrating an anisotropic conductive film according to an eleventh exemplary embodiment;

FIG. 14 is a cross-sectional view taken along line II-II′ of FIG. 13;

FIG. 15 is a schematic plan view illustrating a pixel of a display device;

FIG. 16 is a cross-sectional view taken along line A-A′ of FIG. 15;

FIG. 17 is a plan view illustrating the flow of conductive particles dispersed in a conventional anisotropic conductive film;

FIG. 18 is an enlarged plan view illustrating further details of area B of FIG. 13;

FIG. 19 is an enlarged plan view illustrating further details of area C of FIG. 18;

FIG. 20 is a cross-sectional view taken along line III-III′ of FIG. 18;

FIG. 21 is a cross-sectional view illustrating a conductive pad and a first guide pattern of FIG. 20;

FIG. 22 is a plan view illustrating a conductive pad and a first guide pattern according to a twelfth exemplary embodiment;

FIG. 23 is a plan view illustrating a conductive pad and a first guide pattern according to a thirteenth exemplary embodiment

FIG. 24 is a plan view illustrating a conductive pad and a first guide pattern according to a fourteenth exemplary embodiment;

FIG. 25 is a plan view illustrating a conductive pad and a first guide pattern according to a fifteenth exemplary embodiment; and

FIG. 26 is an enlarged cross-sectional view illustrating a part of a display device according to a sixteenth exemplary embodiment.

### DETAILED DESCRIPTION

Advantages and features of the present invention and methods for achieving them will be made clear from embodiments described below in detail with reference to the accompanying drawings. The present invention may, however, be embodied in many different forms and should not be construed as being limited to the embodiments set forth herein. Rather, these embodiments are provided so that this disclosure will be thorough and complete, and will fully convey the scope of the invention to those skilled in the art. The present invention is merely defined by the scope of the claims. Therefore, well-known constituent elements, operations and techniques are not described in detail in the embodiments in order to prevent the present invention from being obscurely interpreted. Like reference numerals refer to like elements throughout the specification.

The terminology used herein is for the purpose of describing particular example embodiments only and is not intended to be limiting. Throughout the specification, when an element is referred to as being “connected” to another element, the element is “directly connected” to the other element, or “electrically connected” to the other element with one or more intervening elements interposed therebetween. It will be further understood that the terms “comprises,” “comprising,” “includes” and/or “including,” when used in this specification, specify the presence of stated features, integers, steps, operations, elements, and/or components, but do not preclude the presence or addition of one or more other features, integers, steps, operations, elements, components, and/or groups thereof.

In the drawings, the thickness of layers and regions may be exaggerated for clarity. The various Figures are thus not to scale. In addition, when a layer is described to be formed on another layer or on a substrate, this means that the layer may be formed on the other layer or on the substrate, or a third layer may be interposed between the layer and the other layer or the substrate. It will be understood that when an element such as a layer, film, region, or substrate is referred to as being “on” another element, it can be directly on the other element or intervening elements may also be present. In contrast, when an element is referred to as being “directly on” another element, there are no intervening elements present. All numerical values are approximate, and may vary. All examples of specific materials and compositions are to be taken as nonlimiting and exemplary only. Other suitable materials and compositions may be used instead.

Herein, an organic light emitting diode display (OLED) including an organic light emitting layer is described as a display device according to an exemplary embodiment. However, the present invention is not limited thereto and other display devices, such as an LCD device, a plasma display panel (PDP) device, and a field emission display (FED) device, may be used as a display device according to the present invention.

Further, in the drawings, an active-matrix (AM)-type OLED display having a 2Tr-1Cap structure including two thin film transistors (TFT) and a capacitor in each pixel is illustrated. However, the present invention is not limited thereto. In other words, the number of TFTs, capacitors, and wirings of the OLED display is not limited to the configurations herein, and may vary. Herein, the term “pixel” refers to the smallest unit for displaying an image, and the OLED display may display images using a plurality of pixels.

Unless otherwise defined, all terms used herein (including technical and scientific terms) have the same meaning as commonly understood by those skilled in the art to which this invention pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the present specification.

Hereinafter, unless otherwise stated, a substrate may be understood as having the same meaning as a first substrate.

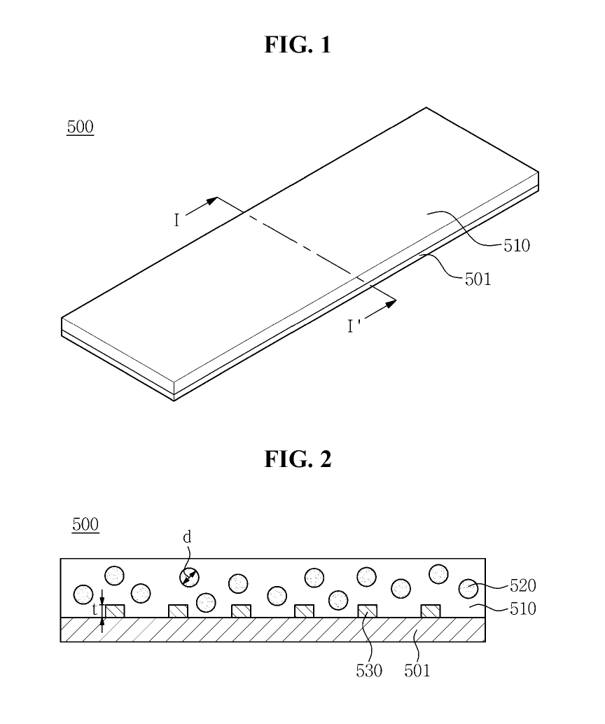

Hereinafter, an anisotropic conductive film according to a first exemplary embodiment will be described with reference to FIGS. 1 to 3.

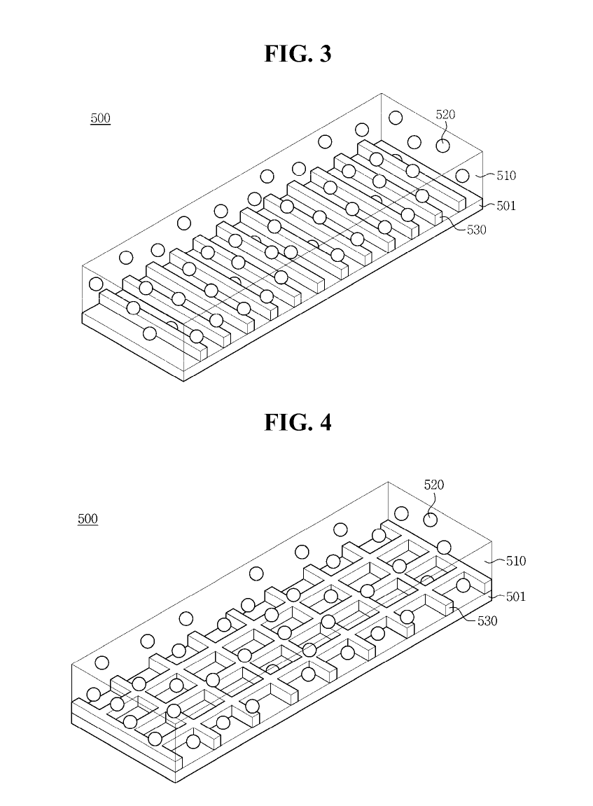

FIG. 1 is a schematic perspective view illustrating an anisotropic conductive film according to the first exemplary embodiment. FIG. 2 is a cross-sectional view taken along line I-I′. FIG. 3 is a schematic perspective view illustrating the inside of the anisotropic conductive film of FIG. 1.

As illustrated in FIGS. 1 to 3, the anisotropic conductive film 500 according to the first exemplary embodiment may include a base film 501, an adhesive layer 510, conductive particles 520, and a first guide pattern 530.

The base film 501 may be attached to the adhesive layer 510 and may include flexible materials. The base film 501 may be detached from the adhesive layer 510 when a substrate is mounted with a driving chip. For example, a driving chip may be mounted on a substrate as follows: a driving chip is attached on a surface of the adhesive layer 510 that is opposite to that which has base film 501 attached thereon; the base film 501 is detached from the adhesive layer 510; and then the exposed surface of the adhesive layer 510 is attached to the substrate.

The adhesive layer 510 may be disposed on the base film 501. The adhesive layer 510 may include resins. When a driving chip is mounted on a substrate, the substrate and the driving chip may be attached to opposing surfaces of the adhesive layer 510. The adhesive layer 510 may melt or may be hardened according to an adhesion method. For example, the adhesive layer 510 may melt with heat or may be hardened by ultraviolet rays. In other words, melting and hardening properties of the adhesive layer 510 may be controlled by varying adhesion methods, and the driving chip may be mounted on a substrate by adjusting the melting or hardening properties of the adhesive layer 510.

At least one conductive particle 520 may be dispersed in the adhesive layer 510. The conductive particles 520 may be insulated from each other by the adhesive layer 510.

The first guide pattern 530 may be formed on a surface of the adhesive layer 510. The first guide pattern 510 may be formed within the adhesive layer 510. The first guide pattern 530 may be provided in a linear pattern and may be provided in plural.

A part of the adhesive layer 510 may be subject to fine pre-curing by laser to thereby form the first guide pattern 530. Accordingly, the first guide pattern 530 may include materials the same as that of the adhesive layer 510, and the hardness of the first guide pattern 530 may be greater than that of the adhesive layer 510. In the display device according to an exemplary embodiment to be described below, the first guide pattern 530 may control flow or positioning of the conductive particles 520 and may guide the conductive particles 520 to be disposed on a conductive pad.

Meanwhile, a height t of the first guide pattern 530 may be less than a diameter d of a conductive particle 520. That is because the conductive particles 520 that flow within the adhesive layer 510 may be damaged if the height t of the first guide pattern 530 is greater than the diameter d of the conductive particle 520.

Hereinafter, anisotropic conductive films according to second to fifth exemplary embodiments will be described in detail with reference to FIGS. 4 to 7.

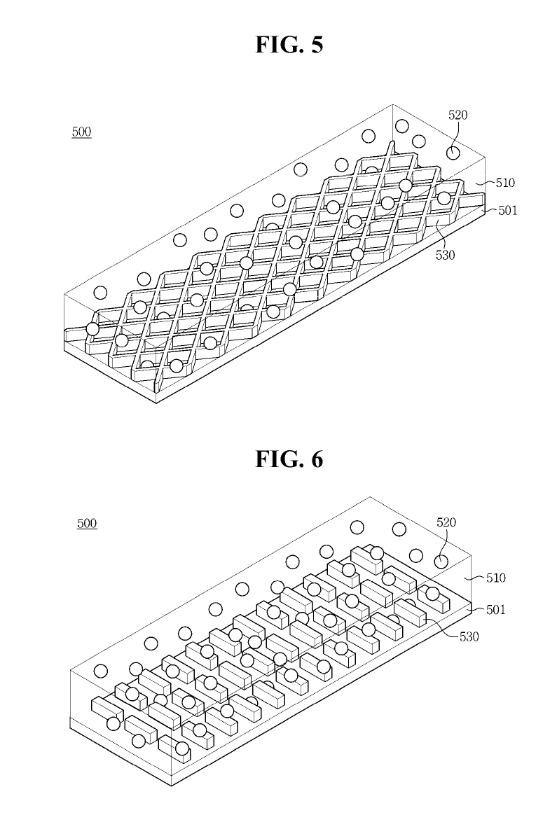

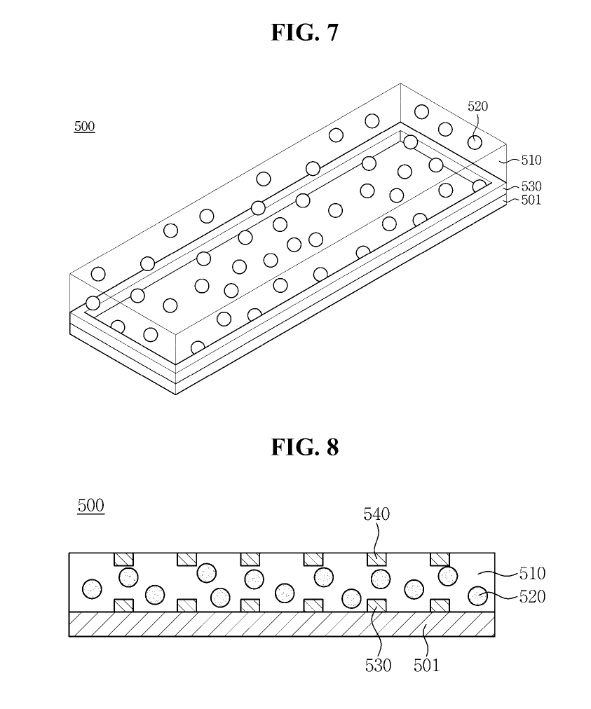

FIG. 4 is a schematic perspective view illustrating an anisotropic conductive film according to a second exemplary embodiment. FIG. 5 is a schematic perspective view illustrating an anisotropic conductive film according to a third exemplary embodiment. FIG. 6 is a schematic perspective view illustrating an anisotropic conductive film according to a fourth exemplary embodiment. FIG. 7 is a schematic perspective view illustrating an anisotropic conductive film according to a fifth exemplary embodiment.

Referring to FIG. 4, the anisotropic conductive film 500 according to the second exemplary embodiment may include a first guide pattern 530 having a mesh pattern and the first guide pattern 530 may have quadrangle-shaped apertures. That is, the first guide pattern 530 may have intersecting lines that extend in two perpendicular directions, forming quadrangular openings therebetween.

Referring to FIG. 5, the anisotropic conductive film 500 according to the third exemplary embodiment may have a first guide pattern 530 having a mesh pattern and the first guide pattern 530 may have lozenge-shaped or rhomboid apertures. That is, the respective linear lines forming the first guide pattern 530 may be diagonally disposed and intersecting, as illustrated in FIG. 5.

Referring to FIG. 6, the anisotropic conductive film 500 according to the fourth exemplary embodiment may include a plurality of first guide patterns 530 spaced apart from each other. The first guide patterns 530 according to the fourth exemplary embodiment may be manufactured by dividing the first guide pattern 530 according to the first exemplary embodiment into two or more parts. FIG. 6 illustrates the first guide patterns 530 respectively divided into three parts, but the number of parts into which the first guide pattern 530 is divided may vary. Any number of parts is contemplated.

Referring to FIG. 7, the anisotropic conductive film 500 according to the fifth exemplary embodiment may include a first guide pattern 530 positioned along an edge of the conductive film 500. The first guide pattern 530 may enclose a plurality of conductive particles 520.

Accordingly, the first guide pattern 530 may be formed into various shapes, and the shape of the first guide pattern 530 may be determined in consideration of factors such as the conductive pad of the substrate, the bump of the circuit member, and the circuit-member mounting area. In other words, the first guide patterns 530 according to the first through fifth exemplary embodiments may be formed to control flow or positioning of the plurality of conductive particles 520 according to each respective configuration of display devices.

Accordingly, the anisotropic conductive films 500 according to the second through fifth exemplary embodiments may have configurations identical to that of the first exemplary embodiment, aside from the shape of the first guide pattern 530.

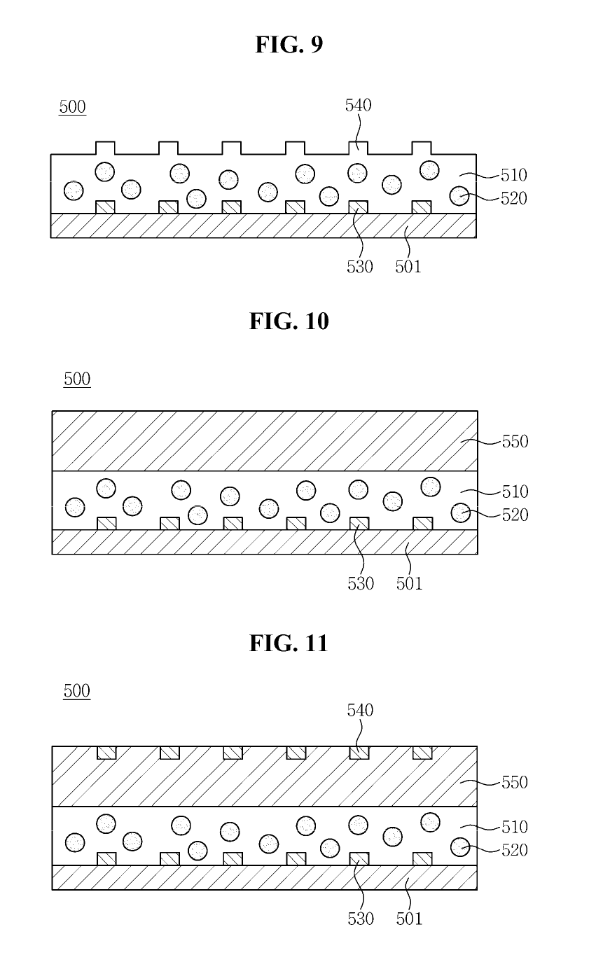

Meanwhile, anisotropic conductive films 500 according to sixth and seventh exemplary embodiments may further include a second guide pattern 540. Hereinafter, the anisotropic conductive film 500 according to sixth through tenth exemplary embodiments will be described with reference to FIGS. 8 and 9.

FIG. 8 is a schematic cross-sectional view illustrating an anisotropic conductive film according to the sixth exemplary embodiment. FIG. 9 is a schematic cross-sectional view illustrating an anisotropic conductive film according to the seventh exemplary embodiment.

Referring to FIG. 8, the anisotropic conductive film 500 according to the sixth exemplary embodiment may further include the second guide pattern 540 on another surface of adhesive layer 510. The second guide pattern 540 may face the first guide pattern 530 and may overlap the first guide pattern 530. Of course, the second guide pattern 540 may not overlap the first guide pattern 530 or may only partially overlap the first guide pattern 530. In other words, the first guide pattern 530 may overlap or may be alternately disposed with the second guide pattern 540 in accordance with a gap between conductive pads (270 of FIG. 18) to be described below. The second guide pattern 540 may be disposed inside or within the adhesive layer 510, and may be formed by performing fine pre-curing on the adhesive layer 510 as in the first guide pattern 530. Accordingly, the hardness of the material of second guide pattern 540 may be greater than the hardness of the material of adhesive layer 510. Meanwhile, the second guide pattern 540 may control flow or location of conductive particles 520 similar to the first guide pattern 530.

Referring to FIG. 9, the anisotropic conductive film 500 according to the seventh exemplary embodiment may further include the second guide pattern 540 protruding from another surface of an adhesive layer 510 (e.g. the surface opposite to that facing the first guide pattern 530). The second guide pattern 540 according to the seventh exemplary embodiment may be formed by performing etching on an upper surface of the adhesive layer 510. Accordingly, the second guide pattern 540 according to the seventh exemplary embodiment may include the same material as that of the adhesive layer 510 and may have hardness substantially equivalent thereto. Thus, pressure applied on the anisotropic conductive film 500 in an anisotropic conductive film compression process may be more precisely controlled for each part of the adhesive layer 510.

Thus, the anisotropic conductive film 500 according to the sixth and seventh exemplary embodiments may have configurations identical to those of the anisotropic conductive film 500 according to the first exemplary embodiment, except for inclusion of the second guide pattern 540.

Meanwhile, the anisotropic conductive films 500 according to eighth to tenth exemplary embodiments may further include a resin layer 550. Hereinafter, the anisotropic conductive films 500 according to the eighth to tenth exemplary embodiments will be described with reference to FIGS. 10 to 12.

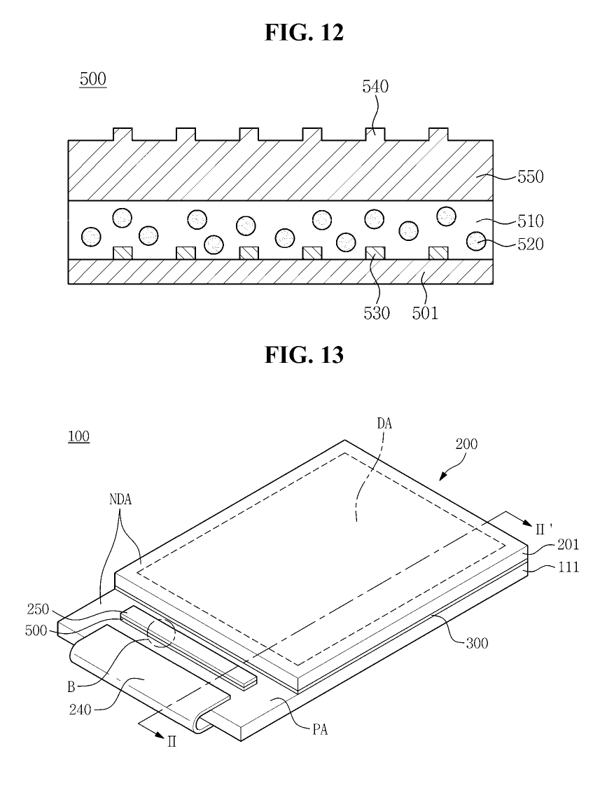

FIG. 10 is a schematic cross-sectional view illustrating the anisotropic conductive film according to the eighth exemplary embodiment. FIG. 11 is a schematic cross-sectional view illustrating the anisotropic conductive film according to the ninth exemplary embodiment. FIG. 12 is a schematic cross-sectional view illustrating the anisotropic conductive film according to the tenth exemplary embodiment.

Referring to FIGS. 10 through 12, the anisotropic conductive films 500 according to the eighth through tenth exemplary embodiments may further include a resin layer 550 on another surface of an adhesive layer 510. The resin layer 550 may include materials the same as those of the adhesive layer 510, and may be a resin within which conductive particles 520 are not dispersed. The resin layer 550 may help to improve adhesion of the anisotropic conductive film 500 to surfaces to which it is connected.

Further, referring to FIG. 11, the anisotropic conductive film 500 according to the ninth exemplary embodiment may include a second guide pattern 540 disposed on a surface of the resin layer 550 that is opposite to the surface adjacent to the adhesive layer 510. The second guide pattern 540 may be disposed inside the resin layer 550 and may be formed by selectively performing pre-curing on parts of the resin layer 550.

Meanwhile, referring to FIG. 12, the anisotropic conductive film 500 according to the tenth exemplary embodiment may include a second guide pattern 540 that may protrude from the resin layer 550. The second guide pattern 540 may be formed of the same materials as those of the resin layer 550, and may be formed by etching the upper surface of resin layer 550.

Accordingly, the anisotropic conductive films 500 according to the eighth to tenth exemplary embodiments may have configurations identical to those of the anisotropic conductive films 500 illustrated in the first, sixth, and seventh exemplary embodiments, except for the added presence of resin layer 550.

In other words, the anisotropic conductive film 500 may basically include a base film 501, the adhesive layer 510, the conductive particles 520, and the first guide pattern 530, and may further include the second guide pattern 540 and the resin layer 550. Further, the second guide pattern 540 may be formed into shapes that are substantially the same as those of the first guide pattern 530 illustrated in the second to fifth exemplary embodiments.

Hereinafter, a display device according to an eleventh exemplary embodiment will be described with reference to FIGS. 13 through 21. The display device according to the eleventh exemplary embodiment may include the aforementioned anisotropic conductive film 500 according to the first exemplary embodiment. In this embodiment, an organic light emitting display device may be used as the display device as a nonlimiting example.

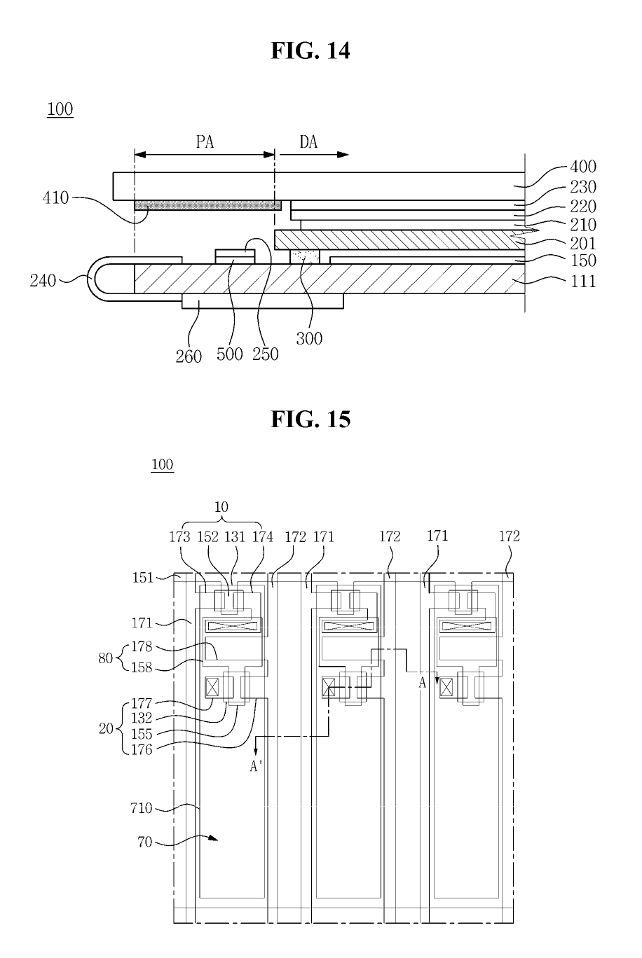

FIG. 13 is a schematic perspective view illustrating a display device according to the eleventh exemplary embodiment. FIG. 14 is a cross-sectional view taken along line II-II′ of FIG. 13.

Referring to FIGS. 13 and 14, an organic light emitting display device 100 according to the eleventh exemplary embodiment may include a display panel 200, a connecting unit 240, a printed circuit board 260, a driving chip 250, an anisotropic conductive film 500, a window 400, and a black matrix 410.

The display panel 200 is a panel to display images and may be an organic light emitting diode panel. The display panel may alternatively and for example be one of the following: an LCD panel, an electrophoretic display panel, a light emitting diode (LED) panel, an inorganic electro luminescent (EL) display panel, a field emission display (FED) panel, a surface-conduction electron-emitter display (SED) panel, a plasma display panel (PDP), and a cathode ray tube (CRT). However, these are illustrated as nonlimiting examples, and any types of display panels, known or otherwise, can be used as the display panel 200 according to an exemplary embodiment.

The display panel 200 may include a first substrate 111, a second substrate 201 positioned opposite to the first substrate 111, a display unit 150, a sealant 300, a touch unit 210, and a polarizing plate 220, but the present invention is not limited thereto. Therefore, the first substrate 111 may be encapsulated by an encapsulation film and the like rather than being covered by the second substrate 201.

The first substrate 111 may include a display area DA for displaying an image by light emission, and a non-display area NDA disposed outside of and surrounding the display area DA. A plurality of pixels is formed in the display area DA on the first substrate 111 to display an image. The display unit 150 may be disposed in the display area DA.

The non-display area NDA may include a pad area PA on which a plurality of conductive pads are formed to receive external signals that may allow the display to project an image. At least one driving chip 250 may be formed on the pad area PA.

The first substrate 111 may be formed of transparent glass materials mainly composed of silicon oxides SiO2. The first substrate 111 is not limited to this material though, and may instead be formed of, for example, transparent plastic materials.

A pad (not illustrated) configured to protect the driving chip 250 from outside shock may be further disposed on the pad area PA. The driving chip 250 may be an integrated circuit (IC) chip such as a driver IC.

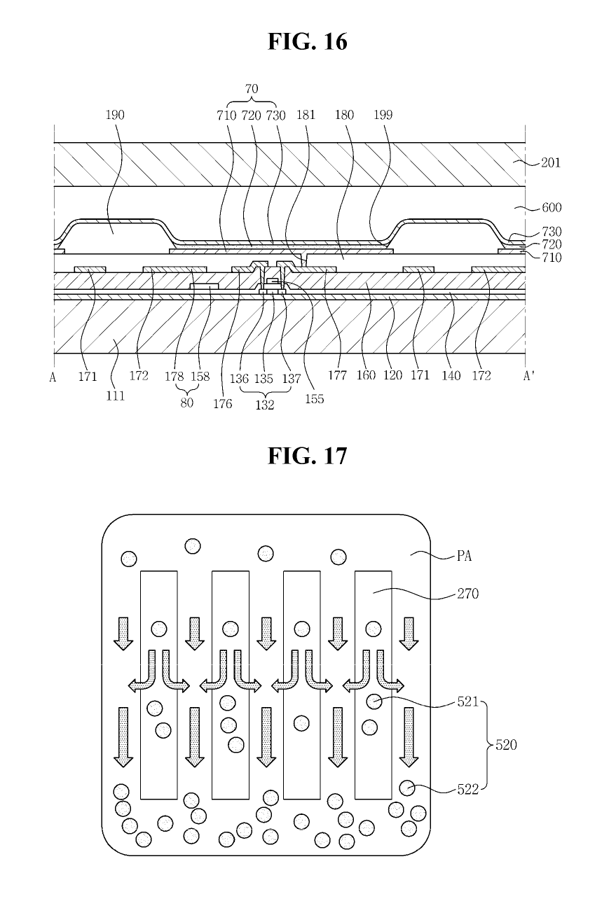

The display unit 150 may be formed on the first substrate 111 and may be connected to the driving chip 250. The display unit 150 may include an OLED and a thin film transistor and wirings to operate it. The display unit 150 will be described below with reference to FIGS. 15 and 16. Instead of an OLED, any elements that may be utilized as a display device may form the display unit 150.

The second substrate 201 may be disposed opposite to the first substrate 111 and bonded to the first substrate 111 via the sealant 300. The second substrate 201 may cover and protect the display unit 150. The second substrate 201 may include a glass substrate, or may include a transparent synthetic resin film as well, such as acrylic. Further, a metal plate may be used as the second substrate 201. For example, the second substrate 201 may be formed of one of a polyethylene (PET) film, a polypropylene (PP) film, a polyamide (PA) film, a polyacetal (POM) film, a poly methyl methacrylate (PMMA) film, a polybutylene terephthalate (PBT) film, a polycarbonate (PC) film, a cellulose film, and moisture-resistant cellophane.

The second substrate 201 may be smaller than the first substrate 111 in size. Accordingly, the pad area PA of the first substrate 111 may be exposed from the second substrate 201.

Further, as for the sealant 300, any suitable material, such as a sealing glass frit, may be used.

The touch unit 210 may be disposed on the second substrate 201 corresponding to the display area DA of the first substrate 111. For example, the touch unit 210 may include first and second electrodes (not illustrated) intersecting each other. The first and second electrodes may be directly patterned on the second substrate 201 to form an on-cell type touch panel, respectively having a plurality of columns in a matrix form. The first and second electrodes may correspond to a touch sensor pattern. Alternatively, the touch unit 210 may be disposed on the second substrate 201 as a separately prepared touch panel.

The touch unit 210 may detect a touch input by a physical touch, such as that from a pen or a user's finger, and may transmit a signal corresponding to the touch location to a touch driver (not illustrated). The touch unit 210 may be used as an input mechanism for the OLED display device 100 and may be formed as a resistive type or a capacitive type touch unit.

The window 400 may include transparent materials, such as glass and resins, and may be configured to protect the display panel 200 so as to prevent breakage or other damage by external shock. For example, the window 400 may be disposed on the touch unit 210 and may cover the display area DA and the pad area PA. The window 400 may be bonded to the second substrate 201 (via the various intervening layers) using a resin 230. The window 400 may be larger than the display panel 200 in size, but is not limited thereto. For example, the window 400 may be formed to have substantially the same size as the display panel 200.

The black matrix 410 is disposed on the window 400 in an area corresponding to the pad area PA. The black matrix 410 may include a printing material that may prevent the pattern disposed under the window 400 from being seen. The printing material may include a black printing material, but the color of the printing material may be modified according to the desired design of the device. As one example, the black matrix 410 may include a light absorbing material such as chromium (Cr).

The polarizing plate 220 may be disposed between the window 400 and the touch unit 210. The polarizing plate 220 may prevent ambient light reflection.

The resin 230 may be disposed between the window 400 and the touch unit 210 and may improve luminance, transmittance, reflectivity, and visibility of the OLED display device 100. The resin 230 may prevent formation of an air gap between the window 400 and the second substrate 201, and may also prevent infiltration of undesired materials like dust. The resin 230 may be photocurable.

The printed circuit board 260 may be a circuit board that applies driving signals to the display panel 200. The printed circuit board 260 may include, for example, a timing controller (not illustrated) configured to generate control signals that may allow the display panel 200 to operate, and a power voltage generator (not illustrated) configured to generate a power voltage.

The printed circuit board 260 may be disposed on a surface of the display panel 200. For example, the printed circuit board 260 may be disposed on a rear surface of the display panel. In general, the display panel 200 may display images on a top surface of the display panel 200, and thus the rear surface of the display panel 200 may be an area which is not be seen by users. Accordingly, in order to maximize space efficiency and hide components that need not be seen by users, the printed circuit board 260 may be disposed on the rear surface of the display panel 200. However, the above is illustrated as an example, and the printed circuit board 260 may be disposed in any desired location, such as on a lateral surface of the display panel 200. As another example, the printed circuit board 260 and a flexible printed circuit board may be integrally formed, where necessary.

The connecting unit 240 may be connected to the pad area PA of the display panel 200. The connecting unit 240 may be electrically connected to the display panel 200 and the printed circuit board 260, thereby providing electrical connection between the display panel 200 and the printed circuit board 260. The connecting unit 240 may be a flexible printed circuit board (FPCB). Alternatively, the connecting unit 240 may be provided as a chip on film including an integrated circuit chip or a tape carrier package.

Although not illustrated, the connecting unit 240, in a cross-sectional view, may include a base film and a wiring pattern on the base film, and may further include a cover film on the wiring pattern. Such a configuration is known.

The base film and the cover film may be formed of a film including materials having flexibility, insulating properties, and thermo-resistant properties. For example, they may include polyimide, but the present invention is not limited thereto, and any materials having these properties are contemplated.

A wiring pattern may be disposed between the base film and the cover film. The wiring pattern may serve to transmit predetermined electric signals, and may include metal materials such as copper (Cu). The surface of the copper wiring may be plated with, for example, tin, silver, or nickel. The wiring pattern may be formed by, for example, casting, laminating, and electroplating. Alternatively, other methods may be employed to form the wiring pattern.

Hereinafter, a pixel of the display unit 150 will be described with reference to FIGS. 15 and 16.

FIG. 15 is a schematic plan view illustrating a pixel of a display device. FIG. 16 is a cross-sectional view taken along line A-A′ of FIG. 15.

FIGS. 15 and 16 illustrate an active-matrix (AM)-type OLED device having a 2Tr-1Cap structure. For example, the 2Tr-1Cap structure includes two TFTs 10 and 20 and a capacitor 80 in each pixel, but the present invention is not limited thereto.

For example, the OLED display device 100 may include three or more TFTs and two or more capacitors 80 in one pixel, and may further include additional lines. Herein, the term “pixel” refers to the smallest unit for displaying an image, and the display area displays an image using a plurality of pixels.

The OLED display device 100 according to an exemplary embodiment may include a first substrate 111 and a plurality of pixels defined on the first substrate 111. Each pixel may include a switching thin film transistor (TFT) 10, the driving TFT 20, the capacitor 80, and the OLED 70. The first substrate 111 may further include a gate line 151 extending along one direction and a data line 171 and a common power line 172 insulated from and intersecting the gate line 151.

Herein, each pixel may be defined by the gate, data, and common power lines 151, 171, and 172, but is not limited thereto.

The OLED 70 may include a first electrode 710, an organic light emitting layer 720 on the first electrode 710, and a second electrode 730 on the organic light emitting layer 720. Herein, at least one first electrode 710 may be formed on each pixel, such that the first substrate 111 may include a plurality of first electrodes 710 spaced apart from each other.

Herein, the first electrode 710 is an anode serving as a hole injection electrode; and the second electrode 730 is a cathode serving as an electron injection electrode. However, the present invention is not limited thereto. For example, the first electrode 710 may be a cathode electrode and the second electrode 730 may be an anode electrode, according to various methods of driving the OLED display device. Further, the first electrode 710 may be a pixel electrode, and the second electrode 730 may be a common electrode.

The holes and electrons injected into the organic light emitting layer 720 are combined with each other to form excitons, and light is emitted by energy generated when the excitons fall from an excited state to a ground state.

The capacitor 80 may include a pair of storage electrodes 158 and 178 with an insulating layer 160 interposed therebetween. Herein, the insulating layer 160 may include a dielectric material. Capacitance of the capacitor 80 is determined by electric charge accumulated in the capacitor 80 and the voltage applied across the pair of storage electrodes 158 and 178.

The switching TFT 10 includes a switching semiconductor layer 131, a switching gate electrode 152, a switching source electrode 173, and a switching drain electrode 174. The driving TFT 20 includes a driving semiconductor layer 132, a driving gate electrode 155, a driving source electrode 176, and a driving drain electrode 177.

The switching TFT 10 may function as a switching element which selects a pixel to perform light emission. The switching gate electrode 152 is connected to the gate line 151, and the switching source electrode 173 is connected to the data line 171. The switching drain electrode 174 is spaced apart from the switching source electrode 173 and connected to the first storage electrode 158.

The driving TFT 20 may apply a driving power to the first electrode 710, which allows the organic light emitting layer 720 of the OLED 70 in a selected pixel to emit light. The driving gate electrode 155 is connected to the first storage electrode 158 that is connected to the switching drain electrode 174. The driving source electrode 176 and the second storage electrode 178 are respectively connected to the common power line 172.

The driving drain electrode 177 is connected to the first electrode 710 of the OLED 70 through a drain contact hole 181.

With the above-described structure, the switching TFT 10 may be operated by a gate voltage applied to the gate line 151 and may function to transmit a data voltage applied to the data line 171 to the driving TFT 20.

Voltage equivalent to a difference between a common voltage applied from the common power line 172 to the driving TFT 20 and the data voltage transmitted from the switching TFT 10 may be stored in the capacitor 80, and current corresponding to the voltage applied to the capacitor 80 may flow to the OLED 70 through the driving TFT 20, so that the OLED 70 may emit light.

The OLED display device 100 according to an exemplary embodiment will be described in more detail with reference to FIGS. 15 and 16.

The OLED display 70, the driving TFT 20, the capacitor 80, the data line 171, and the common power line 172 illustrated in FIG. 15 will be described. Further, a switching semiconductor layer 131, a switching gate electrode 152, and switching source and drain electrodes 173 and 174 of the switching TFT 10 may have the same laminated structure as the driving semiconductor layer 132, the driving gate electrode 155, the driving source and drain electrodes 176 and 177 of the driving TFT 20, and thus a duplicative description will not be provided.

According to an eleventh exemplary embodiment of the present invention, the first substrate 111 may be formed of an insulating substrate formed of glass, quartz, ceramic, plastic or the like. However, the present invention is not limited thereto, and the first substrate 111 may be formed of a metal substrate including stainless steel or the like.

A buffer layer 120 is formed on the first substrate 111. The buffer layer 120 may reduce or prevent infiltration of undesirable elements and may perform a planarization function, and may include various materials in accordance therewith. As an example, the buffer layer 120 may be formed of at least one of a silicon nitride (SiNx), a silicon oxide (SiO2), and a silicon oxynitride (SiOxNy). Alternatively, the buffer layer 120 may be omitted according to the kind of the first substrate 111 and process conditions thereof.

The driving semiconductor layer 132 is formed on the buffer layer 120. The driving semiconductor layer 132 may include at least one semiconductor material such as polycrystalline silicon, amorphous silicon, and an oxide semiconductor. Further, the driving semiconductor layer 132 can include a channel region 135 that is not doped with impurities, and p+ doped source and drain regions 136 and 137 that are formed on both sides of the channel region 135. In this case, p-type impurities, such as boron B, may be doped using, for example, B₂H₆. Such impurities may vary depending on the type of TFT.

A gate insulating layer 140 formed of a silicon nitride or a silicon oxide is formed on the driving semiconductor layer 132. The gate insulating layer 140 may include at least one of tetra ethyl ortho silicate (TEOS), a silicon nitride (SiNx), and a silicon oxide (SiO₂). In some embodiments, the gate insulating layer 140 may have a double-layer structure where a SiNx layer having a thickness of about 40 nm and a TEOS layer having a thickness of 80 nm are sequentially laminated, for example. However, the gate insulating layer 140 is not limited to the aforementioned configuration.

The driving gate electrode 155, the gate line (151 of FIG. 15), and the first storage electrode 158 are formed on the gate insulating layer 140. In this case, the driving gate electrode 155 is formed to overlap at least a part of the driving semiconductor layer 132. For example, the driving gate electrode 155 overlaps the channel region 135. The driving gate electrode 155 may serve to prevent the channel region 135 from being doped with impurities when the source and drain regions 136 and 137 of the driving semiconductor layer 132 are doped with impurities in the forming of the driving semiconductor layer 132.

The gate electrode 155 and the first storage electrode 158 may be formed on the same layer, and may include substantially the same metal material. In this case, the metal material may include at least one of molybdenum (Mo), chromium (Cr), and tungsten (W). In some embodiments, the gate electrode 155 and the first storage electrode 158 may include molybdenum (Mo) or molybdenum alloys.

The insulating layer 160, covering the driving gate electrode 155, is formed on the gate insulating layer 140. The insulating layer 160 may be an interlayer insulating layer. The insulating layer 160 may be formed of a silicon nitride (SiNx) or a silicon oxide (SiOx), which is substantially similar to the gate insulating layer 140. The gate insulating layer 140 and the insulating layer 160 may have contact holes formed therein, to expose the source and drain regions 136 and 137 of the driving semiconductor layer 132.

The driving source and drain electrodes 176 and 177, the data line 171, the common power line 172, and the second storage electrode 178 are disposed on the insulating layer 160 of the display area DA. The driving source and drain electrodes 176 and 177 are respectively connected to the source and drain regions 136 and 137 of the driving semiconductor layer 132 through the above-described contact holes.

As one example, the driving source and drain electrodes 176 and 177, the data line 171, the common power line 172, and the second storage electrode 178 may be formed of refractory metal including at least one of molybdenum, chromium, tantalum, titanium and metal alloys thereof, and may have a multi-layer structure including a refractory metal film and a low-resistance conductive film. The multi-layer structure may include a double-layer structure including a chromium or molybdenum (alloy) lower film and an aluminum (alloy) upper film, or a triple-layer structure including a molybdenum (alloy) lower film, an aluminum (alloy) middle film, and a molybdenum (alloy) upper film.

The present invention is not limited thereto. For example, the driving source and drain electrodes 176 and 177, the data line 171, the common power line 172, and the second storage electrode 178 may be formed of various conductive materials other than the above-described materials.

Accordingly, the driving TFT 20 may be formed to include the driving semiconductor layer 132, the driving gate electrode 155, and the driving source and drain electrodes 176 and 177. However, the configuration of the driving TFT 20 is not limited thereto, and may take on various configurations.

A protective layer 180 is formed on the insulating layer 160 to cover the driving source and drain electrodes 176 and 177, and the like. The protective layer 180 may be formed of organic materials, such as polyacrylates and polyimides. The protective layer 180 may be a planarizing layer.

The protective layer 180 may be formed of at least one of polyacrylate resins, epoxy resins, phenolic resins, polyamide resins, polyimide resins, unsaturated polyester resins, poly-phenylenether resins, poly-phenylenesulfide resins, and benzocyclobutene (BCB).

The drain contact hole 181 may be formed in the protective layer 180 to expose the driving drain electrode 177.

The first electrode 710 is formed on the protective layer 180 and connected to the driving drain electrode 177 through the drain contact hole 181.

A pixel defining layer 190 is formed on the protective layer 180 and partially covers the first electrode 710. The pixel defining layer 190 includes an aperture 199 to expose the first electrode 710.

For example, the first electrode 710 is disposed to correspond to the aperture 199 of the pixel defining layer 190. The pixel defining layer 190 may be formed of resins, such as polyacrylate resins and polyimide resins.

Further, the pixel defining layer 190 may be formed of a photosensitive organic material or a photosensitive polymer material. For example, the pixel defining layer 190 may be formed of one of polyacrylates, polyimides, photo sensitive polyimides (PSPI), photosensitive acryl (PA), and photosensitive novolak resins.

The organic light emitting layer 720 is formed on the first electrode 710 within the aperture 199 of the pixel defining layer 190; and the second electrode 730 may be formed on the pixel defining layer 190 and the organic light emitting layer 720.

Accordingly, the first electrode 710, the organic light emitting layer 720, and the second electrode 730 may form OLED 70.

One of the first and second electrodes 710 and 730 may be formed of a transparent conductive material and the other may be formed of a transflective or reflective conductive material. Depending on the material forming the first and second electrodes 710 and 730, the OLED display device 100 may become a top-emission type, a bottom-emission type, or a both-side-emission type OLED.

For example, when the OLED display device 100 according to the eleventh exemplary embodiment is a top-emission type display device, the first electrode 710 may be formed of a transflective or reflective conductive material, and the second electrode 730 may be formed of a transparent conductive material.

At least one of indium tin oxides (ITOs), indium zinc oxides (IZOs), zinc oxides (ZnOs), and indium oxides (In2O3s) may be used as the transparent conductive material. At least one of lithium (Li), calcium (Ca), lithium fluoride/calcium (LiF/Ca), lithium fluoride/aluminum (LiF/Al), aluminum (Al), silver (Ag), magnesium (Mg), and gold (Au) may be used as the reflective material.

The organic light emitting layer 720 may be formed of low molecular weight organic materials or high molecular weight organic materials. The organic light emitting layer 720 may have a multi-layer structure including a light emitting layer and at least one of a hole injection layer (HIL), a hole transporting layer (HTL), an electron transporting layer (ETL) and an electron injection layer (EIL). For example, the HIL may be disposed on the first electrode 710 and the HTL, light emitting layer, ETL, and EIL may be sequentially laminated thereon.

According to the eleventh exemplary embodiment, the organic light emitting layer 720 is formed only within the aperture 199 of the pixel defining layer 190, but the present invention is not limited thereto. For example, one or more layers of the organic light emitting layer 720 may be disposed not only on the first electrode 710 but also between the pixel defining layer 190 and the second electrode 730, within the aperture 199 of the pixel defining layer 190. For example, the HIL, HTL, ETL, EIL, and other components of the organic light emitting layer 720 may be formed on an area other than the aperture 199 using an open mask, while the light emitting layer of the organic light emitting layer 720 may be formed on each aperture 199 using a fine metal mask (FMM).

Meanwhile, when an LCD device is used as an exemplary embodiment, the first electrode 710 may be physically and electrically connected to the driving drain electrode 177 through the drain contact hole 181 and may receive a data voltage from the driving drain electrode 177. The first electrode 710 receives the data voltage to generate an electric field along with a second electrode (common electrode, not illustrated) that receives a common voltage. This electric field determines a direction of liquid crystal molecules of a liquid crystal layer (not illustrated) positioned between the two electrodes. The first electrode 710 and the second electrode may form a capacitor (hereinafter “a liquid crystal capacitor”), which may maintain an applied voltage although the TFT is turned off.

The second substrate 201 is attached to the first substrate 111 and sealed, with the OLED 70 interposed therebetween. The second substrate 201 may cover and protect the TFTs 10 and 20 and the OLED 70 formed on the first substrate 111, forming a sealed enclosure that prevents infiltration of impurities or foreign objects. An insulating substrate generally formed of glass or plastic may be used as the second substrate 201. When the device is a top-emission type display where an image is displayed toward the second substrate 201, the second substrate 201 may be formed of a light-transmissive material.

Meanwhile, a buffer member 600 is disposed between the first and second substrates 111 and 201. The buffer member 600 may protect inner elements, such as the OLED 70, from external shock applied to the OLED display device 100. The buffer member 600 may increase the reliability of the OLED display device 100. The buffer member 600 may include at least one of an organic sealant such as a urethane-based resin, an epoxy-based resin, and an acrylic resin, and an inorganic sealant such as silicon. A urethane acrylate, for example, may be used as the urethane-based resin. A butyl acrylate and an ethylhexylacrylate, for example, may be used as the acrylic resin.

FIG. 17 is a plan view illustrating the flow of conductive particles dispersed in a conventional anisotropic conductive film.

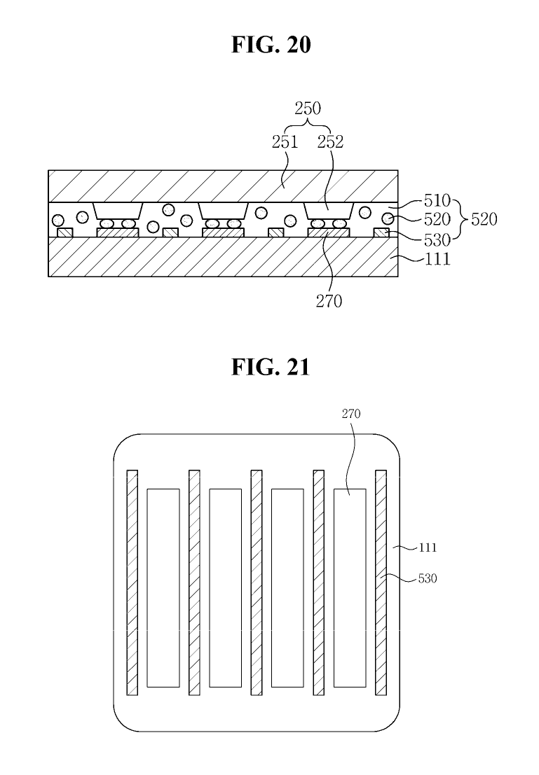

Referring to FIG. 17, in a conventional display device, the number of first conductive particles 521 positioned above the conductive pad 270 is fewer than the number of second conductive particles 522 positioned to the side of the conductive pad 270. That is, conductive particles 521 tend to flow off of the conductive pad 270. As the first conductive particles 521, which are directly involved in electric connection to a circuit member (e.g., a driving chip 250), are fewer in number than the second conductive particles 522, the conductive pad 270 and the driving chip 250 may not be stably connected to each other and a short circuit may be caused between adjacent conductive pads 270 or adjacent bumps (252 of FIG. 20) by the second conductive particles 522.

Accordingly, the anisotropic conductive film 500 according to the first exemplary embodiment may be applicable to the OLED display device according to the eleventh exemplary embodiment, in order to provide more stable electrical connection between the conductive pad 270 and the driving chip 250.

Meanwhile, the base film 501 illustrated in FIG. 1 is to be removed when the anisotropic conductive film 500 is attached to the display device. Accordingly, the anisotropic conductive films 500 according to the eleventh to sixteenth exemplary embodiments may not include the base film 501.

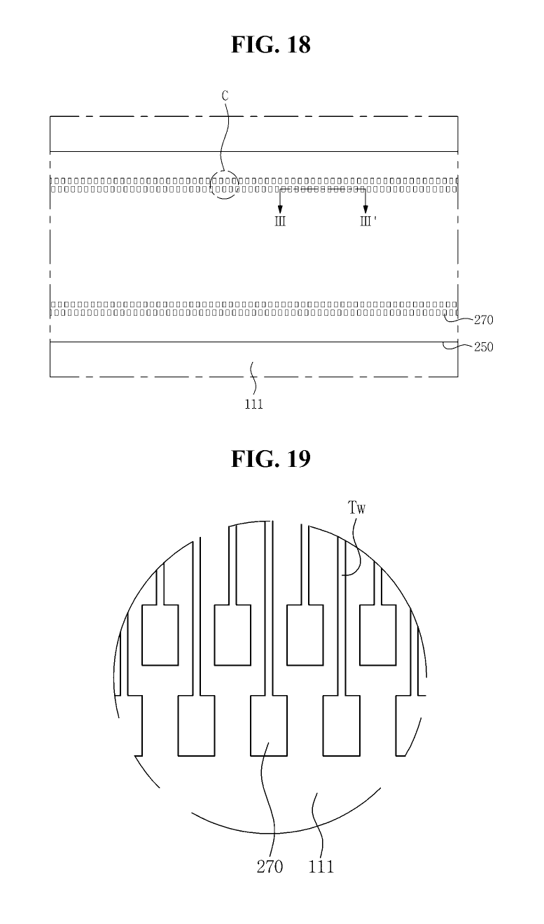

FIG. 18 is an enlarged plan view illustrating further details of area B of FIG. 13. FIG. 19 is an enlarged plan view illustrating further details of area C of FIG. 18.

Referring to FIGS. 18 and 19, each conductive pad 270 may be connected to a thin film wiring TW extending from the display area (150 of FIG. 14). For example, the thin film wiring TW may connect the switching source electrode 173, the switching drain electrode 174, the driving source electrode 176, or the driving drain electrode 177 to the conductive pad 270. The conductive pad 270 may be disposed corresponding to the driving chip 250 and may be connected to the driving chip 250 by the anisotropic conductive film 500.

FIG. 20 is a cross-sectional view taken along line III-III′ of FIG. 18. FIG. 21 is a cross-sectional view illustrating a conductive pad and a first guide pattern of FIG. 20.

Referring to FIGS. 20 and 21, the conductive pad 270 may include materials the same as those of the switching source electrode 173, the switching drain electrode 174, the driving source electrode 176, and the driving drain electrode 177 of the display unit 150 illustrated in FIGS. 14 and 15. However, in the exemplary embodiments, materials forming the conductive pad 270 may not be limited thereto, and may employ any materials used to form the source and drain electrodes of the TFT.

Meanwhile, the anisotropic conductive film 500 may electrically connect the conductive pad 270 to a circuit member, where the circuit member may include the driving chip 250 and the flexible printed circuit board. Hereinafter, the driving chip 250 will be described as an example.

The driving chip 250 may include a driving chip body 251 and bumps 252 extending from the driving chip body 251 and electrically connected to (placed in electrical communication with) conductive pads 270. The driving chip 250 may be connected to the conductive pads 270 to control light emission of the OLED 70. For example, the driving chip 250 may be connected to the conductive pads 270 by the anisotropic conductive film 500 and may apply signals to the switching source electrode 173 and the driving source electrode 176, thereby allowing the organic light emitting layer 720 to emit light. The bumps 252 of the driving chip 250 may be connected to the conductive pads 270 by the conductive particles 520 of the anisotropic conductive film 500.

The driving chip body 251 may include a scan driver (not illustrated) and a data driver (not illustrated) for operating pixels. The bumps 252 may be formed on an area of the driving chip body 251 that overlaps the conductive pads 270.

The driving chip 250 may be mounted on the pad area PA of the first substrate 111 in a chip on glass (COG) manner, so as to be electrically connected to the conductive pad 270. The driving chip 250 may generate scan signals and/or data signals corresponding to the driving power and signals transmitted via the printed circuit board 260. The scan signals and the data signals may be applied to the gate lines 151 and the data lines 171 in the display area DA through the pad electrodes.

Meanwhile, the driving chip 250 may not be necessarily formed in the non-display area NDA, and may be omitted. Further, the driving chip 250 may be mounted on the flexible printed circuit board in a chip on film manner. In other words, a tape carrier package (TCP) in which the driving chip 250 is mounted on a film as a chip may be applicable to the OLED display device 100.

The anisotropic conductive film 500 may connect the driving chip 250 and the conductive pads 270, such that the driving chip 250 may be mounted on the first substrate 111. The anisotropic conductive film 500 may be disposed between the conductive pads 270 and the bumps 252 to electrically connect the conductive pads 270 and the bumps 252. The anisotropic conductive film 500 may include the adhesive layer 510, the conductive particles 520, and the first guide pattern 530.

The adhesive layer 510 may be disposed between the driving chip 250 and the first substrate 111, and may bond the driving chip 250 to the first substrate 100. Within the adhesive layer 510, a plurality of conductive particles 520 may be present, and the adhesive layer 510 may prevent short circuit formation between adjacent conductive particles 520.

At least one conductive particle 520 may be dispersed within the adhesive layer 510 and between a bump 252 and a conductive pad 270. This particle 520 may electrically connect the bump 252 and the conductive pad 270.

The first guide pattern 530 may be formed on a surface of the adhesive layer 510 adjacent to the conductive pad 270. The first guide pattern 530 may include materials the same as those of the adhesive layer 510. The adhesive layer 510 may be partially cured to thereby form the first guide pattern 530, as above. Accordingly, the first guide pattern 530 may be disposed inside the adhesive layer 510 and may have a hardness greater than that of the adhesive layer 510. The first guide pattern 530 may be provided in a linear pattern.

Further, the first guide pattern 530 may be alternately disposed with respect to the conductive pads 270 and the bumps 252, and may control flow of the conductive particle 520. As the first guide pattern 530 is disposed between adjacent conductive pads 270 and bumps 252, the possibility of the conductive particles 520 being disposed between a conductive pad 270 and its associated bump 252 may increase. In other words, the first guide pattern 530 is configured to push the conductive particles 520 disposed between the conductive pads 270 upwards, above the conductive pad 270. Further, the density of the conductive particles 520 dispersed within the adhesive layer 510 may be higher between the first guide patterns 530 than it is on the first guide pattern 530. Accordingly, the first guide pattern 530 may electrically connect the conductive pads 270 and the bumps 252 with fewer numbers of conductive particles 520, and may reduce the possibility that the conductive particles 520 cause short circuits.

Meanwhile, as illustrated in FIG. 2, the first guide pattern 530 may have a height t less than a diameter d of the conductive particles 520. That is because the conductive particles 520 that flow within the adhesive layer 510 may be damaged if the height t of the first guide pattern 530 is greater than the diameter d of the conductive particles 520.

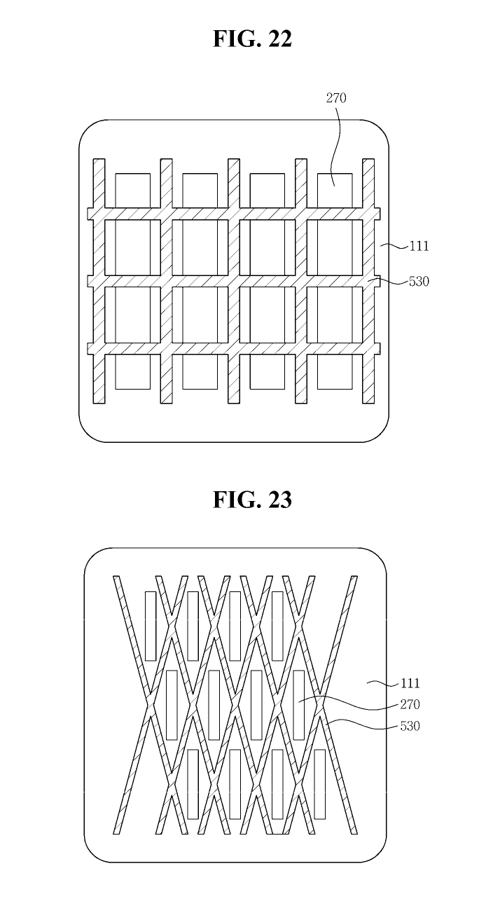

Hereinafter, twelfth to sixteenth exemplary embodiments will be described with reference to FIGS. 22 through 26. Each of the exemplary embodiments describes various shapes of the first guide pattern 530 that may control flow of the conductive particles 520.

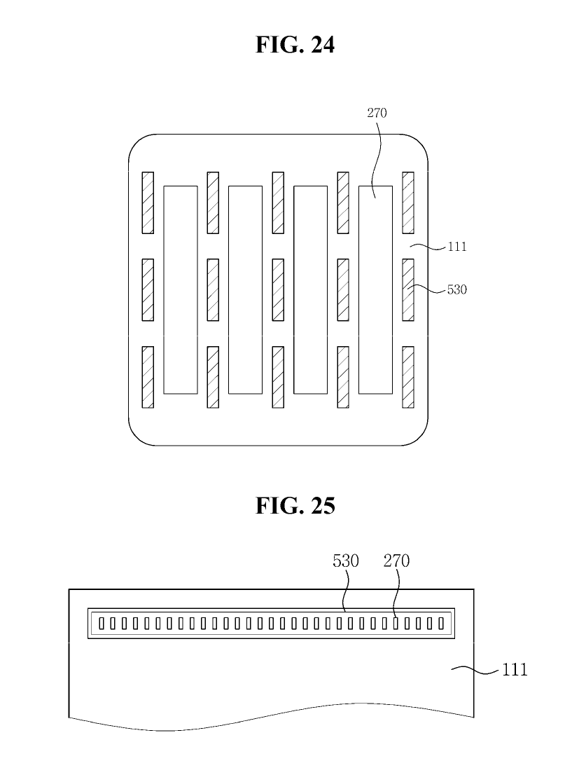

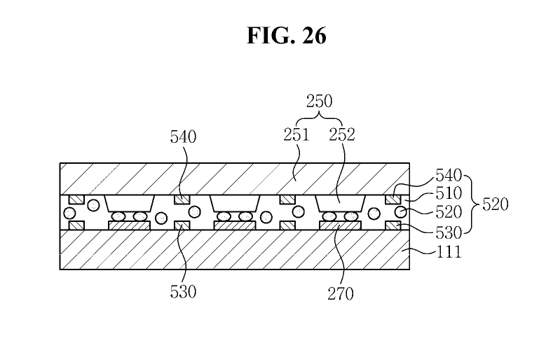

FIG. 22 is a plan view illustrating a conductive pad and a first guide pattern according to a twelfth exemplary embodiment. FIG. 23 is a plan view illustrating a conductive pad and a first guide pattern according to a thirteenth exemplary embodiment. FIG. 24 is a plan view illustrating a conductive pad and a first guide pattern according to a fourteenth exemplary embodiment. FIG. 25 is a plan view illustrating a conductive pad and a first guide pattern according to a fifteenth exemplary embodiment. FIG. 26 is an enlarged cross-sectional view illustrating a part of a display device according to a sixteenth exemplary embodiment.

Referring to FIG. 22, an anisotropic conductive film according to the twelfth exemplary embodiment may include a first guide pattern 530 having a mesh pattern as illustrated in the second exemplary embodiment, and the first guide pattern 530 may intersect the conductive pads 270 and bumps 252. The first guide pattern 530 may have a plurality of apertures each having a quadrangular shape. The first guide pattern 530 may include longitudinal lines extending in a direction the same as a longitudinal direction of the conductive pad 270, and transverse lines intersecting the conductive pads 270. The first guide pattern 530 provided in a mesh pattern may control flow of conductive particles 520 more accurately than that of the eleventh exemplary embodiment.

Referring to FIG. 23, an anisotropic conductive film 500 according to the thirteenth exemplary embodiment may include a first guide pattern 530 having a mesh pattern as illustrated in the third exemplary embodiment (see FIG. 5), and the first guide pattern 530 may intersect the conductive pads 270 and bumps 252. The first guide pattern 530 may have a plurality of apertures each having a lozenge, rhomboid, or diamond shape. In other words, each line forming the first guide pattern 530 may be diagonally disposed as illustrated in FIG. 23. As display devices of high-definition are developed, the conductive pads 270 in a display device may be broken into two to three columns and the first guide pattern 530 according to the thirteenth exemplary embodiment may be applicable to, i.e. may extend between, the conductive pads 270 alternately disposed in two or more columns.

Referring to FIG. 24, an anisotropic conductive film 500 according to the fourteenth exemplary embodiment may include a plurality of first guide patterns 530 spaced apart from each other as illustrated in the fourth exemplary embodiment (see FIG. 6). In other words, each first guide pattern 530 according to the eleventh exemplary embodiment may be divided into two or more discrete and spaced-apart parts. The first guide pattern 530 may be disposed between conductive pads 270 and may be formed in a variety of shapes that may allow the control of flow or positioning of conductive particles 520. In other words, the first guide pattern 530 may be provided in, for example, a nonlinear shape such as a circular, polygonal, or pillar shape, in consideration of the position, number, and shape of the conductive pads 270 and bumps 252.

Referring to FIG. 25, an anisotropic conductive film 500 according to the fifteenth exemplary embodiment may include a first guide pattern 530 on an edge portion thereof as illustrated in the fifth exemplary embodiment (see FIG. 7). The first guide pattern 530 may enclose the conductive pad 270. In other words, the first guide pattern 530 may control or restrict flow of conductive particles 520, to allow the conductive particles 520 to be disposed only in an area where the conductive pads 270 are disposed.

Referring to FIG. 26, an anisotropic conductive film 500 according to the sixteenth exemplary embodiment may further include a second guide pattern 540 disposed on another surface of an adhesive layer 510. The second guide pattern 540 may be disposed between conductive pads 270 and bumps 252, to be alternately disposed with respect to the conductive pads 270 and the bumps 252, and may overlap a first guide pattern 530. The second guide pattern 540 may overlap, or may be alternately disposed with respect to, the first guide pattern 530 based on a gap between the conductive pads 270. In other words, when the gap between the conductive pads 270 is less than the sum of a line width of the first guide pattern 530 and a line width of the second guide pattern 540, the first guide pattern 530 and the second guide pattern 540 may overlap each other.

The second guide pattern 540 may be formed on the opposite side of the adhesive layer 510 as that on which the first guide pattern 530 is formed, may be disposed inside the adhesive layer 510, and may include materials the same as those of the adhesive layer 510. The second guide pattern 540 may be formed by performing curing of a part of the adhesive layer 510 and may have hardness greater than that of the adhesive layer 510.

As both the first guide pattern 530 and second guide pattern 540 are present, flow of the conductive particles 520 may be controlled more accurately. In other words, as the first and second guide patterns 530 and 540 are positioned between the conductive pads 270 and bumps 252, the possibility of the conductive particle 520 to be disposed between the conductive pad 270 and the bump 252 may increase. That is, the guide patterns 530, 540 act as a barrier that guides particles 520 back toward the pads 270 and bumps 252.

Meanwhile, a height of the second guide pattern 540 may be less than a diameter of the conductive particle 520. That is because the conductive particles 520 that flow within the adhesive layer 510 may be damaged if the height of the second guide pattern 540 is greater than the diameter of the conductive particle 520.

Further, although not illustrated in the drawings, the anisotropic conductive film 500 according to the seventh to tenth exemplary embodiments illustrated in FIGS. 9 through 12 may be applicable to the display device. In other words, as illustrated in FIG. 9, the anisotropic conductive film 500 including the second guide pattern 540 protruding from the upper surface of the adhesive layer 510 may be applicable to the display device and the second guide pattern 540 may allow pressure applied on the anisotropic conductive film 500 to be controlled for each part of the adhesive layer 510. Further, as illustrated in FIGS. 10 through 12, the anisotropic conductive film 500 further including a resin layer 550 on the adhesive layer 510 may be applicable to the display device. As the resin layer 550 is further provided, adhesion force between the driving chip 250 and the first substrate 111 may be improved.

Meanwhile, the second guide patterns 540 respectively illustrated in FIGS. 9 through 12 may be broken and then removed in the compression of the anisotropic conductive film 500. In other words, the second guide pattern 540 protruding from the adhesive layer 510 or from the resin layer 550 may be subject to pressure and may be dented, being compressed between the circuit member and the first substrate 111.

From the foregoing, it will be appreciated that various embodiments in accordance with the present disclosure have been described herein for purposes of illustration, and that various modifications may be made without departing from the scope and spirit of the present teachings. Accordingly, the various embodiments disclosed herein are not intended to be limiting of the true scope and spirit of the present teachings. Furthermore, different features of the various embodiments, disclosed or otherwise understood, can be mixed and matched in any manner to produce further embodiments within the scope of the invention.

What is claimed is:

1. A display device comprising:
a substrate having a pad area;
a conductive pad on the pad area;
a circuit member on the conductive pad, the circuit member comprising a bump overlapping the conductive pad; and
an anisotropic conductive film between the conductive pad and the bump, the anisotropic conductive film electrically connecting the conductive pad and the bump, wherein the anisotropic conductive film comprises:
an adhesive layer;
at least one conductive particle positioned within the adhesive layer; and
a first guide pattern positioned at a surface of the adhesive layer adjacent to the conductive pad.

2. The display device of claim 1, further comprising a second guide pattern positioned at another surface of the adhesive layer.

3. The display device of claim 2, wherein at least part of the first guide pattern overlaps the second guide pattern.

4. The display device of claim 2, wherein the first guide pattern and the second guide pattern are disposed within the adhesive layer.

5. The display device of claim 4, wherein the first guide pattern and the second guide pattern each have a hardness greater than a hardness of the adhesive layer.

6. The display device of claim 1, further comprising a resin layer on another surface of the adhesive layer, the resin layer having a first surface facing the adhesive layer and a second surface opposite to the first surface; and
a second guide pattern positioned at the second surface of the resin layer.

7. The display device of claim 1, wherein the conductive particles have a higher density between the first guide patterns than on the first guide pattern.

8. The display device of claim 2, further comprising a plurality of the conductive pads and a plurality of the bumps, ones of the conductive pads positioned to correspond to ones of the bumps so as to form pairs of the conductive pads and bumps, wherein the first guide pattern and the second guide pattern are disposed in alternating manner with the pairs of the conductive pads and bumps.

9. The display device of claim 2, further comprising a plurality of the conductive pads and a plurality of the bumps, wherein the first guide pattern and the second guide pattern are disposed in alternating manner with respect to at least one of the conductive pads and at least one of the bumps.

10. The display device of claim 2, wherein the first guide pattern and the second guide pattern each have a height less than a diameter of the conductive particle.

11. The display device of claim 2, wherein the first guide pattern and the second guide pattern are provided in one of a linear pattern and a mesh pattern.

12. The display device of claim 1, wherein the circuit member is one of a driving chip and a flexible printed circuit board.

13. An anisotropic conductive film comprising:
a base film;
an adhesive layer on the base film;
at least one conductive particle positioned within the adhesive layer; and
a first guide pattern positioned at a surface of the adhesive layer.

14. The anisotropic conductive film of claim 13, further comprising a second guide pattern positioned at another surface of the adhesive layer.

15. The anisotropic conductive film of claim 14, wherein the first guide pattern and the second guide pattern are disposed within the adhesive layer.

16. The anisotropic conductive film of claim 15, wherein the first guide pattern and the second guide pattern each have a hardness greater than a hardness of the adhesive layer.

17. The anisotropic conductive film of claim 14, wherein the first guide pattern is disposed within the adhesive layer, and
the second guide pattern protrudes from another surface of the adhesive layer.

18. The anisotropic conductive film of claim 17, wherein the first guide pattern has a hardness greater than a hardness of the adhesive layer, and the second guide pattern has a hardness substantially the same as the hardness of the adhesive layer.

19. The anisotropic conductive film of claim 13, further comprising a resin layer on another surface of the adhesive layer, the resin layer having a first surface facing the adhesive layer and a second surface opposite to the first surface; and
a second guide pattern positioned at the second surface of the resin layer.

20. The anisotropic conductive film of claim 14, wherein the first guide pattern and the second guide pattern each have a height less than a diameter of the conductive particle.
